(19) United States
(12) Patent Application Publication
(10) Pub. No.: US 2015/0325468 A1
(43) Pub. Date: Nov. 12, 2015

(54) METHOD FOR PREPARING MATERIAL ON INSULATOR BASED ON ENHANCED ADSORPTION

(71) Applicant: SHANGHAI INSTITUTE OF MICROSYSTEM AND INFORMATION TECHNOLOGY, CHINESE ACADEMY OF SCIENCES, Shanghai (CN)

(72) Inventors: Miao ZHANG, SHANGHAI (CN); Da CHEN, Shanghai (CN); Zengfeng DI, Shanghai (CN); Zhongying XUE, Shanghai (CN); Xing WEI, Shanghai (CN); Gang WANG, Shanghai (CN)

(21) Appl. No.: 14/402,213

(22) PCT Filed: Mar. 21, 2013
(86) PCT No.: PCT/CN2013/072972

§ 371 Date: Nov. 19, 2014

(30) Foreign Application Priority Data
Jan. 23, 2013 (CN) 201210024414.3

(51) Int. Cl. H01L 21/762

(52) U.S. Cl. CPC H01L 21/76254; H01L 21/76256

(57) ABSTRACT

Provided is a method for preparing a material on an insulator based on enhanced adsorption. In the method: first, a single crystal film having a doped superlattice structure, an intermediate layer, a buffer layer and a top layer film are epitaxially grown in succession on a first substrate; then, low dosage ion implantation is performed on the structure on which the top layer film is formed, so that ions are implanted above an upper surface or below a lower surface of the single crystal film having a doped superlattice structure; next, a second substrate having an insulation layer is bonded to the structure on which ion implantation has already been performed, and an annealing treatment is performed, so that a microscopic crack is produced at the single crystal film having a doped superlattice structure to achieve atomic-scale stripping. The effective stripping of bonding wafers is achieved by means of enhanced adsorption. The stripped surface is smooth and has a low roughness, and the quality of the crystal of the top layer film is high.

### BACKGROUND OF THE PRESENT INVENTION

1. Field of Invention

The present invention relates to the preparation field of semiconductor material, and particularly to a method for preparing a material on an insulator based on enhanced adsorption.

2. Description of Related Arts

Silicon on insulator (SOI) is a structure that forming a layer of single crystal silicon film onto an insulator substrate, or a formed structure of single crystal silicon film that separated from a supported silicon substrate by an insulating layer (generally SiO₂), and such kind of material structure may totally isolate the film structure with the substrate material of manufacturing devices.

In numerous SOI fabrication techniques, separation with implanted oxygen (SIMOX) technology, Bonded and Etch-back SOI (BESOT) technology are dominant technologies, and the main advantage of adopting SIMOX technology is that both silicon layer and buried layer have good homogeneity, since wafer surface is taken as a reference surface during oxygen implantation, such that excellent homogeneity for top silicon film and buried layer (BOX) can be achieved during annealing; however, this technology requires a high-energy (neutralization for big beam) ion implantation equipment (implantation of oxygen or nitrogen) and a high temperature annealing for a long time, and features high cost.

Smart-cut technology is a new manufacturing technology for SOI wafer that has been developed over the past few years, and is constructed based on the combination of ion implantation and bonding technologies, and its ingenuity lies that bubbles are formed by H⁺ implantation and heating up, so that a crack is produced at depths of implantation of a wafer

For example, as shown in FIGS. 1a to 1c, a Si wafer 11 is performed with H⁺ ion implantation, then the Si wafer 11 is bonded with a Si wafer 12 having SiO₂ layer on the surface at low temperature; next, perform heat treatment for the bonding wafer, such that the Si wafer 11 is isolated with the distributed peak position of H atom, wherein a thin layer of single crystal Si is bonded with the Si wafer 12 to form SOI structure; finally, perform high temperature annealing and polishing, which may enhance the bond strength and recover the damage caused by the H⁺ ion implantation in the top layer Si; chemical-mechanical polishing may be adopted to improve surface homogeneity. Furthermore, stripped Si wafer 11 is reusable.

However, the above method requires large dose, high-energy ion implantation, it also requires a chemical-mechanical polishing to improve surface homogeneity, due to the poor surface homogeneity after stripping that results from the large dose of ion implantation. Besides, the above method is hard to prepare a material on an ultra-thin insulator.

### SUMMARY OF THE PRESENT INVENTION

In view of the advantages of the prior art, the object of the present invention is to provide a method for preparing a material on an insulator based on enhanced adsorption.

In order to achieve the above object and other related objects, the present invention is to provide a method for preparing a material on an insulator based on enhanced adsorption, which at least comprise steps:

a) a single crystal film having a doped superlattice structure, an intermediate layer, a buffer layer and a top layer film are epitaxially grown in succession on a first substrate;

b) low dosage ion implantation is performed on the structure on which the top layer film is formed, so that ions are implanted above an upper surface or below a lower surface of the single crystal film having a doped superlattice structure;

c) a second substrate having an insulation layer is bonded to the structure on which ion implantation has already been performed, and an annealing treatment is performed, so that a microscopic crack is produced at the single crystal film having a doped superlattice structure to achieve atomic-scale stripping.

Preferably, doping material includes one or more of C, B, P, Ga, In, As, Sb.

Preferably, the superlattice structure is one or a mixture of several of Si/Si₁₋ₓGeₓ (0<x≦1), Si₁₋ₓGeₓ/Si_{1-y}Ge_{y} (0<x, y≦1), Si/Ge, SiGe/Ge, Ge/GaAs, GaAs/AlGaAs, GaAs/InAs, AlN/GaN, GaN/InN, and the thickness of the single crystal film is between 3 nm and 20 nm.

Preferably, the intermediate layer material is one of IV element, III-V element, II-VI element, and nitrogen, with a thickness no less than 50 nm.

Preferably, the buffer layer material is one of IV element, III-V element, II-VI element, and nitrogen, with a thickness no less than 50 nm.

Preferably, the top layer film material is one of IV element, III-V element, II-VI element, and nitrogen, with a thickness more than or equal to 5 nm.

Preferably, the ion implantation dosage is more than or equal to 3E16/cm².

Preferably, in step c), the bonding is performed by a plasma enhanced bonding method.

Preferably, the method for preparing a material on an insulator based on enhanced adsorption further comprises: d) during the preparation of a material on an insulator, a chemical etching is performed on the structure after stripping, to remove the intermediate layer and the buffer layer.

Preferably, the insulating layer is one of glass, aluminum oxide, titanium dioxide, silicon dioxide, silicon nitride and aluminum nitride.

From the above, the method for preparing a material on an insulator based on enhanced adsorption of the present invention is based on a strong adsorption power of the single crystal film having a doped superlattice structure to ions, and bond with the oxide wafer after the ion implantation with a low dosage, such that a microscopic crack is produced at the single crystal film having a doped superlattice structure to achieve atomic-scale stripping. The stripped surface is smooth and has a low roughness, and the quality of the crystal of the top layer film is high, without a smoothness treatment by a chemical-mechanical polishing.

### BRIEF DESCRIPTION OF THE DRAWINGS

FIGS. 1a to 1c show a preparation flow diagram of a silicon on insulator of the prior art.

FIGS. 2a to 2f show a flow diagram of a method for preparing a material on an insulator based on enhanced adsorption of the present invention.

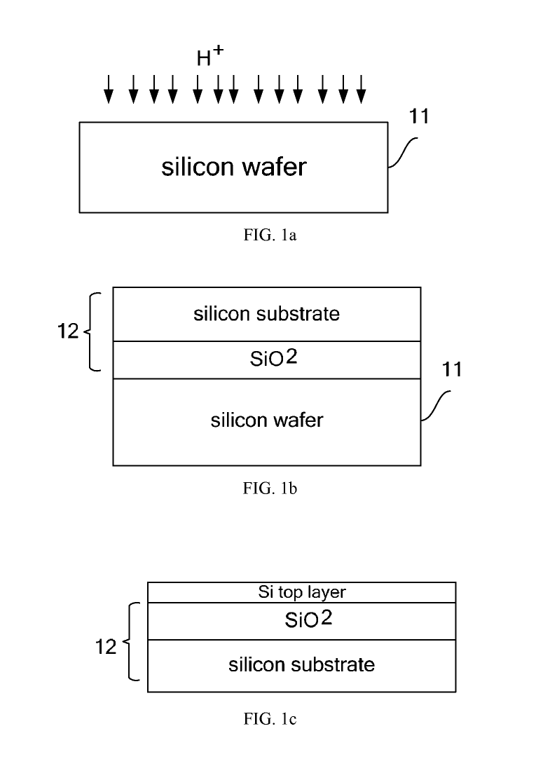

Instructions of component labels

| | |
|---|---|
| 11, 12 | silicon wafer |
| 21 | silicon substrate |
| 22 | single crystal film |
| 23 | Si intermediate layer |
| 24 | SiGe buffer layer |
| 25 | Si top layer |
| 31 | oxide wafer |

### DETAILED DESCRIPTION OF THE PREFERRED EMBODIMENTS

### Embodiment 1

The embodiment modes of the present invention are described hereunder through specific examples, and persons skilled in the art may easily understand other advantages and efficacies of the present invention from the contents disclosed in the present description. The present invention may be further implemented or applied through other different specific embodiment modes, and various modifications or amendments may also be made to each of the details in the present description based on different perspectives and applications without departing from the spirit of the present invention.

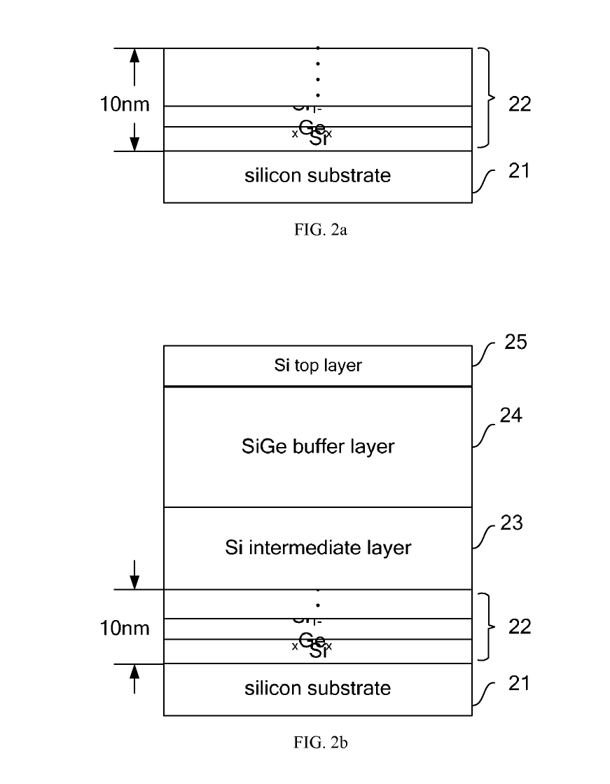

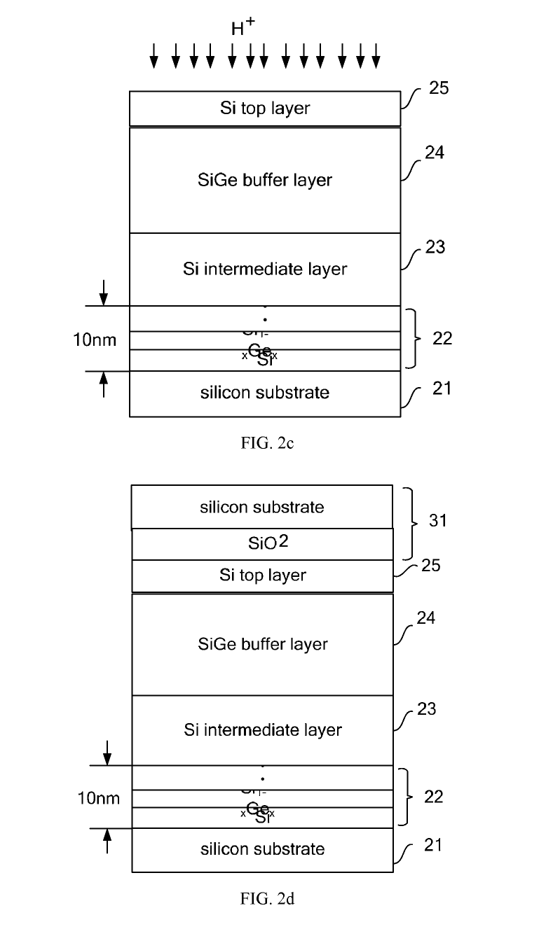

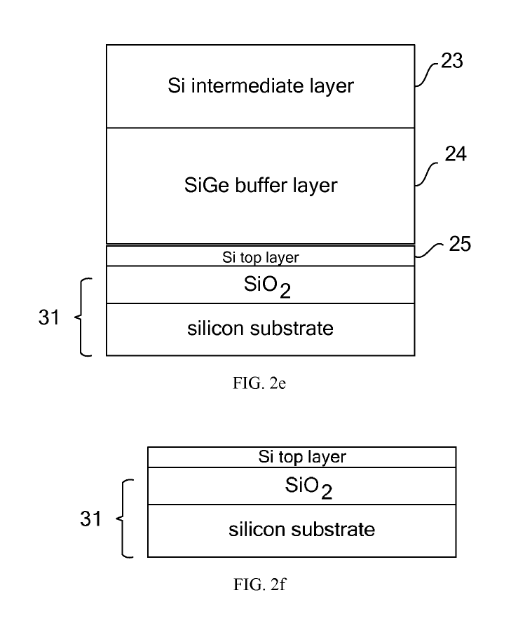

Please refer to FIG. 2a to FIG. 2f. It is to be noted that the drawings provided in the present embodiment only explain the basic conception of the present invention in an illustrative manner, so the drawings only display the components relevant to the present invention rather than being drawn according to the number, shape and size of the components during actual implementation, the shape, number and scale of each component may be randomly changed during its actual implementation, and the layout of the components thereof might also be more complicated.

As shown in figures, a method for preparing a material on an insulator based on enhanced adsorption of the present invention at least comprises the following steps:

First step: a single crystal film having a doped superlattice structure is epitaxially grown on a first substrate.

Wherein, the doping material includes but not limits to: one or more of C, B, P, Ga, In, As, Sb, the formed superlattice structure may be: one or more of Si/Si₁₋ₓGeₓ (0<x≦1), Si₁₋ₓGeₓ/Si_{1-y}Ge_{y} (0<x, y≦1), Si/Ge, SiGe/Ge, Ge/GaAs, GaAs/AlGaAs, GaAs/InAs, AlN/GaN, GaN/InN and the like, and the thickness of the single crystal film is preferably between 3 nm and 20 nm.

For example, a single crystal film 22 having a B-doped Si/Si₁₋ₓGeₓ (0<x≦1) superlattice structure is epitaxially grown on a Si substrate, with a thickness of 10 nm, as shown in FIG. 2a.

Second step, an intermediate layer, a buffer layer and a top layer film are epitaxially grown in succession on the single crystal film.

Wherein, the intermediate layer material may be IV element, such as Si, SiGe, Ge, Si₁₋ₓCₓ, Si_{1-x-y}CₓGe_{y}, etc., and may also be III-V element, such as AlP, AlAs, AlSb, GaP, GaAs, InP, InAs, AlGaAs, etc., as well as II-VI element, such as ZnS, ZnSe, ZnTe, CdS, CdSe, HgTe etc., and may be nitrogen, such as MN, GaN, InN, etc., with a thickness no less than 50 nm; the buffer layer material may be IV element, such as Si, SiGe, Ge, Si₁₋ₓCₓ, Si_{1-x-y}CₓGe_{y}, etc., and may also be III-V element, such as AlP, AlAs, AlSb, GaP, GaAs, InP, InAs, AlGaAs, etc., as well as II-VI element, such as ZnS, ZnSe, ZnTe, CdS, CdSe, HgTe etc., and may be nitrogen, such as MN, GaN, InN, etc., with a thickness no less than 50 nm; the top layer film material may be IV element, such as Si, SiGe, Ge, Si₁₋ₓCₓ, Si_{1-x-y}CₓGe_{y}, etc., and may also be III-V element, such as AlP, AlAs, AlSb, GaP, GaAs, InP, InAs, AlGaAs, etc., as well as II-VI element, such as ZnS, ZnSe, ZnTe, CdS, CdSe, HgTe etc., and may be nitrogen, such as MN, GaN, InN, etc., with a thickness more than 5 nm;

For example, a Si intermediate layer 23 is further epitaxially gown on a surface of the single crystal film 22, with a thickness of 100 nm; then, a SiGe buffer layer is further epitaxially gown, with a thickness of 160 nm; next, a Si top layer 25 is further epitaxially gown, with a thickness of 20 nm, as shown in FIG. 2b.

Third step: a low dosage ion implantation is performed on the structure on which the top layer film has been formed, so that ions are implanted above an upper surface or below a lower surface of the single crystal film having a doped superlattice structure.

Wherein, the ion implantation may adopt hydrogen ions or hydrogen and helium ions, with an implantation dosage more than or equal to 3E16/cm² (≧3E16/cm²), and an implantation depth above an upper surface or below a lower surface of the single crystal film. Experimental results prove that, the single crystal film having a doped superlattice structure has strong adsorption to H ions. Moreover, compared to the implantation depth above an upper surface, the implantation depth above an upper surface features a stronger adsorption for ions.

For example, perform an H ion implantation on the structure as shown in FIG. 2b, with an implantation dosage of 3E16/cm², and an implantation depth 40 nm below the lower surface of the single crystal film 22, as shown in FIG. 2c.

Fourth step: a second substrate having an insulation layer is bonded to the structure on which ion implantation has already been performed, and an annealing treatment is performed, so that a microscopic crack is produced at the single crystal film having a doped superlattice structure to achieve atomic-scale stripping.

In this embodiment, the insulating layer is one of glass, aluminum oxide, titanium dioxide, silicon dioxide, silicon nitride and aluminum nitride. Certainly, the insulating layer may also be some other kinds of expected insulating material, but not limited to the listed various types herein.

For example, a plasma enhanced bonding method is adopted to perform a bonding of the ion implanted structure and the oxide wafer 31, as shown in FIG. 2d. Then, perform annealing treatment, the condition of which is that: in O₂, 300° for 120 min, and 600° for 300 min, so that a microscopic crack is produced at the single crystal film having a doped superlattice structure to achieve atomic-scale stripping. The formed material on insulator is shown in FIG. 2e, with a smooth stripped surface, and there is no need for a smoothness treatment by a chemical-mechanical polishing.

Preferably, as required, a chemical etching is further preformed on the structure after stripping, to remove the intermediate layer and the buffer layer.

For example, perform a chemical etching and polishing treatment on the structure of material on insulator as shown in FIG. 2e, to form the structure of material on insulator as shown in FIG. 2f.

To sum up, in the method for preparing a material on an insulator based on enhanced adsorption of the present invention, the single crystal film having a doped superlattice structure is formed on the silicon wafer, thus the adsorption to ions can be greatly enhanced; besides, when bond with the oxide wafer after a low dosed ion implantation, atomic-scale stripping can be effectively achieved. Since the ion implantation features a low dosage, the stripped surface is smooth, and has a low roughness, and the quality of the crystal of the top layer film is high, without a smoothness treatment by a chemical-mechanical polishing. Therefore, the present invention effectively overcomes a variety of advantages in the prior art, and features higher industrial utilization value.

The abovementioned embodiments only illustratively describe the principle and efficacy of the present invention, rather than being used to limit the present invention. Any person skilled in the art may modify or amend the abovementioned embodiments without departing from the spirit and scope of the present invention. Thus, all equivalent modifications or amendments accomplished by persons having common knowledge in the technical field concerned without departing from the spirit and technical thoughts revealed by the present invention shall still be covered by the claims of the present invention.

What is claimed is:

1. A method for preparing a material on an insulator based on enhanced adsorption, characterized in that, the method for preparing a material on an insulator based on enhanced adsorption at least comprise steps:
a) a single crystal film having a doped superlattice structure, an intermediate layer, a buffer layer and a top layer film are epitaxially grown in succession on a first substrate;
b) low dosage ion implantation is performed on the structure on which the top layer film is formed, so that ions are implanted above an upper surface or below a lower surface of the single crystal film having a doped superlattice structure;
c) a second substrate having an insulation layer is bonded to the structure on which ion implantation has already been performed, and an annealing treatment is performed, so that a microscopic crack is produced at the single crystal film having a doped superlattice structure to achieve atomic-scale stripping.

2. The method for preparing a material on an insulator based on enhanced adsorption according to claim 1, characterized in that, doping material includes one or more of C, B, P, Ga, In, As, Sb.

3. The method for preparing a material on an insulator based on enhanced adsorption according to claim 1, characterized in that, the superlattice structure is one or a mixture of several of Si/Si₁₋ₓGeₓ (0<x≦1), Si₁₋ₓGeₓ/Si_{1-y}Ge_{y} (0<x, y≦1), Si/Ge, SiGe/Ge, Ge/GaAs, GaAs/AlGaAs, GaAs/InAs, AlN/GaN, GaN/InN and the thickness of the single crystal film is between 3 nm and 20 nm.

4. The method for preparing a material on an insulator based on enhanced adsorption according to claim 1, characterized in that, the intermediate layer material is one of IV element, III-V element, II-VI element, and nitrogen, with a thickness no less than 50 nm.

5. The method for preparing a material on an insulator based on enhanced adsorption according to claim 1, characterized in that, the buffer layer material is one of IV element, III-V element, II-VI element, and nitrogen, with a thickness no less than 50 nm.

6. The method for preparing a material on an insulator based on enhanced adsorption according to claim 1, characterized in that, the top layer film material is one of IV element, III-V element, II-VI element, and nitrogen, with a thickness more than or equal to 5 nm.

7. The method for preparing a material on an insulator based on enhanced adsorption according to claim 1, characterized in that, the ion implantation dosage is more than or equal to 3E16/cm².

8. The method for preparing a material on an insulator based on enhanced adsorption according to claim 1, characterized in that, which method further comprises step: d) during the preparation of a material on an insulator, a chemical etching is preformed on the structure after stripping, to remove the intermediate layer and the buffer layer.

9. The method for preparing a material on an insulator based on enhanced adsorption according to claim 1, characterized in that, the insulating layer is one of glass, aluminum oxide, titanium dioxide, silicon dioxide, silicon nitride and aluminum nitride.
